(19) United States
(12) Patent Application Publication
(10) Pub. No.: US 2022/0140582 A1
(43) Pub. Date: May 5, 2022

(54) ELECTRICAL COMPONENT HOUSING WITH COOLING CHANNELS

(71) Applicant: Lear Corporation, Southfield, MI (US)

(72) Inventors: Jordi CLARAMUNT BLANCO, Valls (ES); Xavier CARBONELL MATE, Valls (ES)

(21) Appl. No.: 17/085,072

(22) Filed: Oct. 30, 2020

(51) Int. Cl. H02G 3/03; H05K 7/20

(52) U.S. Cl. CPC H02G 3/03; H05K 7/20218

(57) ABSTRACT

A housing for electrical components is provided with a substrate. Sidewalls extend from the substrate to define a cavity configured to receive electrical components. A cooling channel is formed integrally along and unitary with the substrate, spaced apart from the cavity, with a mating surface for at least one fluid cover. At least one fluid cover is mountable on the mating surface for at least one fluid cover to enclose the cooling channel and to redirect a fluid when present within the cooling channel.

### TECHNICAL FIELD

Various embodiments relate to housings for electrical components with cooling channels.

### BACKGROUND

U.S. Pat. No. 9,332,676 B2 to Sharaf et al. of Lear Corporation, discloses a sealed battery charger housing with cooling channels.

The prior art has also provided a sealed battery charger with cooling ingress and egress ports in a first sidewall of a housing. A cooling channel extends from the ingress port partially along the first sidewall to an intersection with a second sidewall that is perpendicular to the first sidewall. The cooling channel extends along the length of the second sidewall. The cooling channel is then redirected to return partially along the length of the second sidewall to an intermediate position. The cooling channel then extends along an intermediate wall that is perpendicular with the second sidewall. The intermediate wall is oriented within the housing to extend to an intermediate position in a third sidewall. The third sidewall is spaced apart from, and generally parallel with, the second sidewall. The cooling channel then extends partially along the third sidewall to an end of the third sidewall. Then, the cooling channel is redirected to return and extend along the length of the third sidewall to the first sidewall. Then the cooling channel extends partially along the first sidewall to the egress port.

### SUMMARY

According to an embodiment, a housing for electrical components is provided with a substrate. Sidewalls extend from the substrate to define a cavity configured to receive electrical components. A cooling channel is formed integrally along and unitary with the substrate, spaced apart from the cavity, with a mating surface for at least one fluid cover. At least one fluid cover mountable on the mating surface for at least one fluid cover to enclose the cooling channel and to redirect a fluid when present within the cooling channel.

According to a further embodiment, the cooling channel is formed through a lateral pair of the sidewalls.

According to another further embodiment, the cooling channel is enclosed within the housing except through the sidewalls.

According to another further embodiment, the cooling channel is further defined as a plurality of cooling channels formed integrally along and unitary with the substrate, spaced apart from the cavity.

According to an even further embodiment, a plurality of mating surfaces for the at least one fluid cover is formed along the sidewalls only.

According to another even further embodiment, the plurality of mating surfaces for the at least one fluid cover is formed upon a pair of spaced apart and opposed lateral sidewalls of the housing.

According to yet another even further embodiment, the housing has a height in a direction parallel with the sidewalls, a width, and a length greater than the width. The plurality of mating surfaces for the at least one fluid cover is formed along the length of the housing.

According to another even further embodiment, a plurality of covers, are each mounted to one of the plurality of mounting surfaces to enclose the plurality of cooling channels.

According to another even further embodiment, one of the plurality of covers limits fluid communication between a sequential pair of the plurality of cooling channels.

According to another even further embodiment, a sequential pair of the plurality of cooling channels are interconnected by a first cooling channel portion formed along one of the lateral sidewalls.

According to another even further embodiment, one of the plurality of covers provides a second cooling channel portion cooperating with the first cooling channel portion of the housing interconnecting the sequential pair of the plurality of cooling channels.

According to another further embodiment, an inlet port and an outlet port to the plurality of cooling channels are formed in the plurality of covers.

According to another further embodiment, each sequential pair of the plurality of cooling channels are interconnected by a first cooling channel portion formed along one of the lateral sidewalls.

According to another even further embodiment, each of the plurality of covers provides a second cooling channel portion cooperating with one of the first cooling channel portions of the housing interconnecting each sequential pair of the plurality of cooling channels.

According to another further embodiment, a structural fin is provided within the cooling channel.

According to another further embodiment, the cooling channel is formed with draft angles in a lateral direction to mold the housing.

According to another embodiment, a housing for electrical components is provided with a substrate. Sidewalls extend from the substrate to define a cavity to receive electrical components. A cooling channel is formed integrally along the substrate spaced apart from the cavity and enclosed within the housing except through a lateral pair of sidewalls.

According to another embodiment, a method of manufacturing a housing for electrical components, translates a first mold die in a first direction toward a second mold die to close a mold. A pair of mold inserts are translated centrally into a mold cavity in directions perpendicular to the first direction to provide cooling cavities in the housing. Thermally conductive material is cast into the mold cavity to form the housing with a substrate generally perpendicular to the cooling cavities to receive electrical components. The pair of mold inserts are translated out of the mold cavity. The first mold die is translated away from the second mold die to open the mold. The housing is removed from the mold cavity.

According to a further embodiment, cooling covers are installed on lateral sides of the housing to enclose the cooling cavities. Electrical components are installed upon the substrate of the housing.

According to another further embodiment, at least two cooling ports are provided in the cooling covers.

According to another embodiment, a housing for electrical components is formed from a method of manufacturing, that translates a first mold die in a first direction toward a second mold die to close a mold. A pair of mold inserts are translated centrally into a mold cavity in directions perpendicular to the first direction to provide cooling cavities in the housing. Thermally conductive material is cast into the mold cavity to form the housing with a substrate generally perpendicular to the cooling cavities to receive electrical components. The pair of mold inserts are translated out of the mold cavity. The first mold die is translated away from the second mold die to open the mold. The housing is removed from the mold cavity.

### BRIEF DESCRIPTION OF THE DRAWINGS

FIG. 1 is an exploded perspective view of an electrical component housing according to an embodiment;

FIG. 2 is a partial section view taken along section line 2-2 of the electrical component housing of FIG. 1;

FIG. 3 is an enlarged partial exploded perspective view of the electrical component housing of FIG. 1 illustrating a cover according to an embodiment;

FIG. 4 is a partial section view taken along section line 4-4 of the electrical component housing of FIG. 3;

FIG. 5 is an enlarged perspective view of the electrical component housing of FIG. 1 illustrating a cover according to another embodiment;

FIG. 6 is an enlarged perspective view of the electrical component housing of FIG. 1 illustrating a cover according to another embodiment;

FIG. 7 is a schematic view of the electrical component housing of FIG. 1 illustrating a manufacturing step according to an embodiment;

FIG. 8 is perspective view of an electrical component housing according to another embodiment; and

FIG. 9 is a section view taken along section line 9-9 of the electrical component housing of FIG. 8.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

On-board vehicle battery chargers include electronic components that conduct high current, which consequently transmits a high heat. In order to manage the heat of such applications, fluid cooling vessels have been provided to cool the chargers. The fluid cooling vessels often include a body with a cavity and a cover that are sealed with a gasket and screws. Silicone and ultraviolet-curing gaskets have been provided. Alternatively, the covers have been friction stir-welded to the body.

The prior art has provided cooling fluid vessels, often referred to as cold-plates. The cold-plates are often formed of aluminum and include a housing with sidewalls defining a cavity with a cover enclosing the cavity. The cover is often sealed to the housing with a gasket, such as a silicone gasket or an ultraviolet-cured gasket. Such gasketed vessel assemblies are often held together with threaded fasteners. Alternatively, the prior art has friction stir welded covers to cavity housings. However, market demands require the seals to pass enhanced specifications to increased fluid pressures, vibrations and chemical agents, while also requesting a reduction in costs.

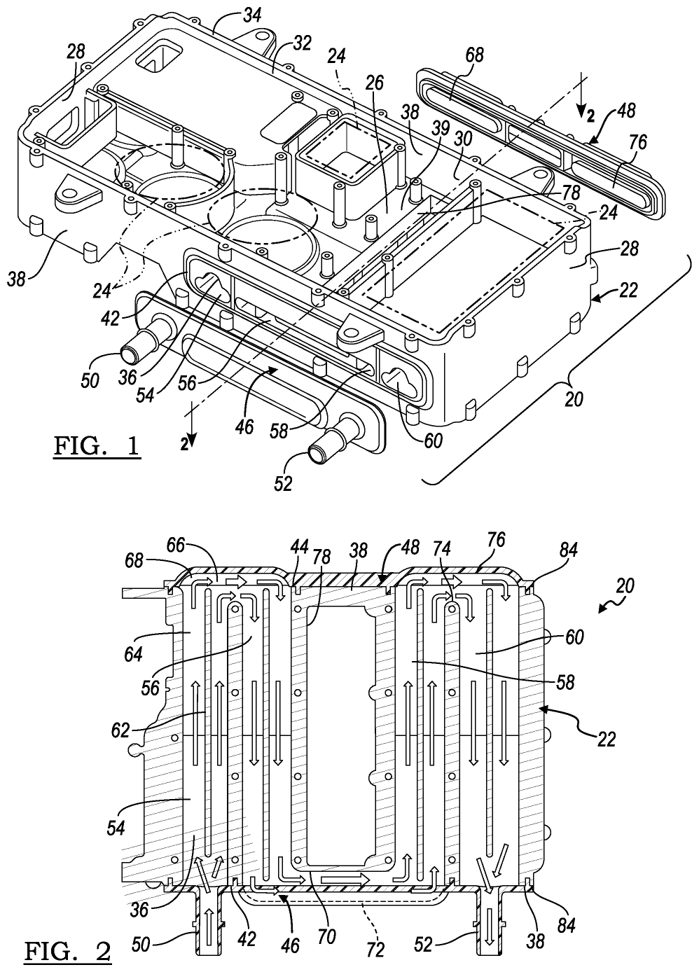

FIG. 1 illustrates a partially exploded view of a housing assembly 20 according to an embodiment. The housing assembly 20 includes a housing 22 formed of a thermally conductive material, such as aluminum. The housing 22 is for housing electrical components 24, which may be electrical components 24 for an onboard vehicle charger. The housing 22 is formed from aluminum for conducting heat away from the electrical components 24.

The housing 22 includes a substrate 26 and a plurality of sidewalls 28 extending from the substrate 26. The sidewalls 26 are generally perpendicular to the substrate 26 according to an embodiment. The substrate 26 and the sidewalls 28 collectively provide a cavity 30 for receiving and enclosing the electrical components 24. The substrate 26 may also be located within a center of the housing 22, whereby a cavity 30 is provided on both sides of the substrate 26, each to receive and cool electrical components 24. The sidewalls 28 collectively terminate at an opening 32. Although the housing 22 is illustrated with four sidewalls 28, any suitable quantity of sidewalls 28 may be employed. A mating surface 34 is formed about the opening 32 for attachment of a cover for enclosing and concealing the electrical components 24.

The housing 22 includes a cooling channel 36 formed integrally along and spaced apart from a mounting surface 39 of the substrate 26 for the electrical components 24. If both surfaces of the substrate 26 include mounting surfaces 39 for the electrical components 24, then the cooling channel 36 is provided between the mounting surfaces 39. The cooling channel 36 is formed unitary with the housing 22. The cooling channel 36 is oriented within the substrate 26 for cooling the electrical components 24 in the cavity 30. As will be explained, the cooling channel 36 structurally enhances the housing 22, and reduces material excesses, while cooling the electronic components 24. The cooling channel 36 is formed from a plurality of cooling channel segments formed through a pair 38 of lateral sidewalls 28 of the housing 22. FIG. 2 is a cross section through the cooling channel 36 illustrating the cooling channel segments.

With reference to FIGS. 1 and 2, the housing 22 has a height as defined by the mating surface 34 to an opposed mounting surface of the housing 22. The housing 22 also has a length and a width as defined by the area of the mating surface 34 and the opening 32 to the cavity 30. The cooling channel segments of the cooling channel 36 are each formed through the lateral pair 38 of sidewalls 28 of the housing 22, along the length of the housing 22. The cooling channel 36 is enclosed within the housing 22 except for through the lateral pair 38 of sidewalls 28.

A mating surface 42, 44 is formed in each of the sidewalls 28 of the lateral pair 38. The mating surfaces 42, 44 are formed about the cooling channel segments of the cooling channel 36. Each of the mating surfaces 42, 44 are sized to receive a cover 46, 48. The covers 46, 48 are affixed to the mating surfaces 42, 44 to enclose the cooling channel segments and to complete the cooling channel 36 as one cooling circuit. The covers 46, 48 each form part of the fluid circuit. The covers 46, 48 enclose the cooling channel 36, and are utilized to direct and redirect the fluid circuit. Additionally, the covers 46, 48 are also utilized to separate sequential segments of the cooling circuit. The covers 46, 48 may each be formed from a polymeric material, or a thermally conductive material, such as aluminum. The cooling covers 46, 48 are provided along the lateral pair 38 of sidewalls 28 to minimize the size of the covers 46, 48 and to minimize deformation of the substrate 26 under pressurized conditions.

One of the covers 46 includes a pair of ports 50, 52, which may be an inlet port 50 and an outlet port 52. The ports 50, 52 extend from the cover 46 for attachment and fluid communication with fluid couplings such as coolant hoses. Although the ports 50, 52 are illustrated mounted to the same cover 46, the ports 50, 52 could be mounted to different covers 46, 48 if beneficial for the cooling channel 36. Additionally, any number of cooling channels 36 and ports 50, 52 may be employed depending upon the cooling specifications of the applicable housing 22.

As illustrated in FIG. 2, the cooling channel segments include a first cooling channel segment 54, a second cooling channel segment 56, a third cooling channel segment 58 and a fourth cooling channel segment 60. A path of the cooling fluid in the cooling circuit is illustrated by arrows in FIG. 2. A cooling fin 62 is provided in each cooling channel segment 54, 56, 58, 60. The cooling fins 62 connect the substrate 26 to a base 64 of the housing 22 beneath the cooling channel 36. The cooling fins 62 add additional surface area to the cooling channel 36 to enhance heat transfer from the electrical components to a fluid within the cooling channel 36. The cooling fins 62 also provide structural beams between the substrate 26 and the base 64 to structurally enhance both surfaces 26, 64 and to reduce unsupported regions, which may otherwise be susceptible to deformation.

A first cooling channel connection portion 66 is formed within one of the lateral pair 38 of sidewalls 28, between the first cooling channel segment 54 and the second cooling channel segment 56. The first cooling channel connection portion 66 permits the cooling fluid to pass from the first cooling channel segment 54 to the second cooling channel segment 56. A complementary second cooling channel connection portion 68 is formed in the cover 48 and aligned with the first cooling channel segment 54 and the second cooling channel segment 56. The second cooling channel connection portion 68 is shaped to receive coolant from the first cooling channel segment 54 and redirect the coolant towards and into the second cooling channel segment 56. Each sequential pair of cooling channel segments, first 54 and second 56, second 56 and third 58, and third 58 and fourth 60 may include a cooling channel connection portion 66, 70, 74 formed in one of the pair 38 of sidewalls 28, and a cooling channel connection portion 68, 72, 76 formed into one of the covers 46, 48.

The covers 46, 48 are also each utilized to separate the cooling channel segments 54, 56, 58, 60. For example, the cover 46 separates the first cooling channel segment 54 and the second cooling channel segment 56. The cover 48 separates the second cooling segment 56 and the third cooling segment 58. The cover 46 separates the third cooling segment 58 and the fourth cooling segment 60. By separating cooling channel segments 54, 56, 58, 60, the covers 46, 48 provide closure with the sidewalls 38 of the housing 28 to eliminate undesired passthrough of the cooling liquid.

The housing 22 with the cooling channel 36 and covers 46, 48 permits various arrangements and configurations of the cooling channel 36. For example, a bypass opening 78 may be formed through the base 64 and the substrate 26 for electrical interconnection through the housing 22 from one cavity 30 to another cavity 30. This design flexibility removes design restrictions regarding locations for placing features and electrical components 24 within the housing 22.

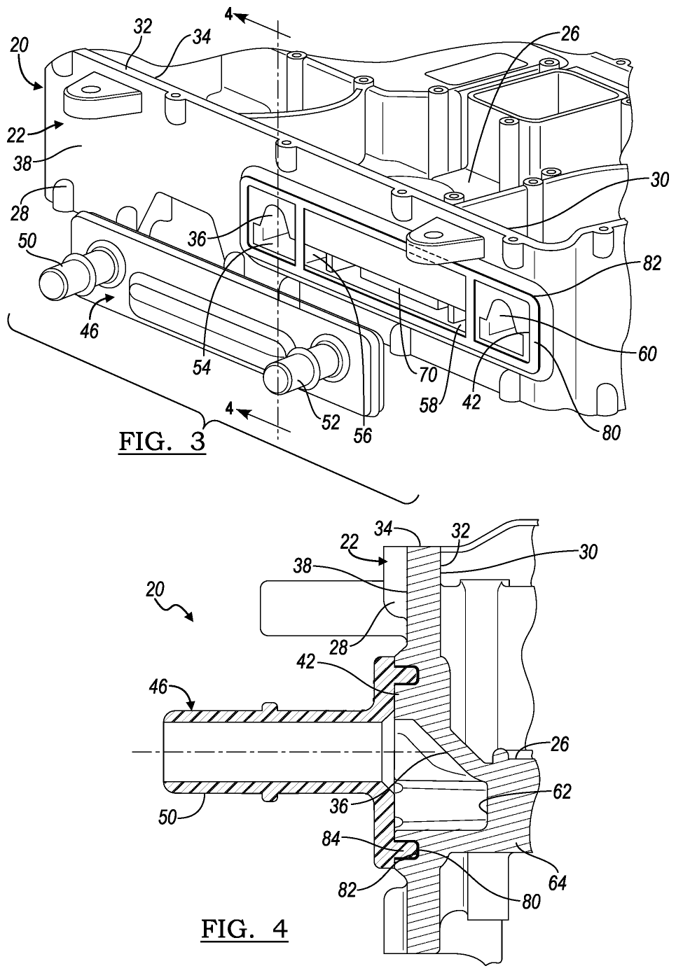

Any suitable method or fastener for connecting the covers 46, 48 to the mating surfaces 42, 44 may be employed. Referring now to FIGS. 3 and 4, a channel 80 is formed into the mating surface 42, 44 according to an embodiment. An adhesive 82 is dispensed into the adherent channel 80. Each cover 46, 48 is provided with a projection 84 with a plurality of adherent surfaces and is sized to be inserted into the adherent channel 80. The adhesive 82 affixes the projection 84 within the channel 80, thereby fastening each cover 46, 48 to the applicable mating surface 42, 44. Additionally, the adhesive provides a fluid tight seal between the covers 46, 48 and the housing 22. Blanco Figueras et al. U.S. Patent Application Publication No. 2020/0088476 A1, which published to Lear Corporation on Mar. 19, 2020 discloses various suitable adhesive connections, which is hereby incorporated by reference herein.

In the prior art, a cooling cavity is provided beneath the substrate as a fluid cooling chamber that is enclosed by another cover, that is fastened or welded to the housing with a cooling channel formed into both the housing and the cooling cover. In order to fasten the cooling cover to the housing, additional volume is required in the housing for the fastener locations or mating surfaces for a cooling cavity sealed enclosure. If electrical components are provided on one side of the substrate in some prior art housings, leakage through the cooling cover may be to the exterior of the housing. Due to some large prior art cooling chambers, the cooling cover may bulge or deform because of pressure from the cooling liquid circuit. Likewise, the substrate may deform, thereby stressing the electrical components installed upon the substrate.

The housing assembly 20 is more compact by removing a cooling channel cover from within the housing 22, which would also require space for fasteners or welding. By removing a cooling channel cover in a height direction, and the associated fasteners, additional surface area is provided for electrical components 24. A risk of leakage is removed from within the housing 22 and designed to be relocated outside of the housing 22. By integrating the cooling channel surface beneath the substrate 26, stresses and deformations are removed from the electrical components 24. These advantages are provided while also improving cooling by adding additional cooling fins 62 within the cooling channel 36.

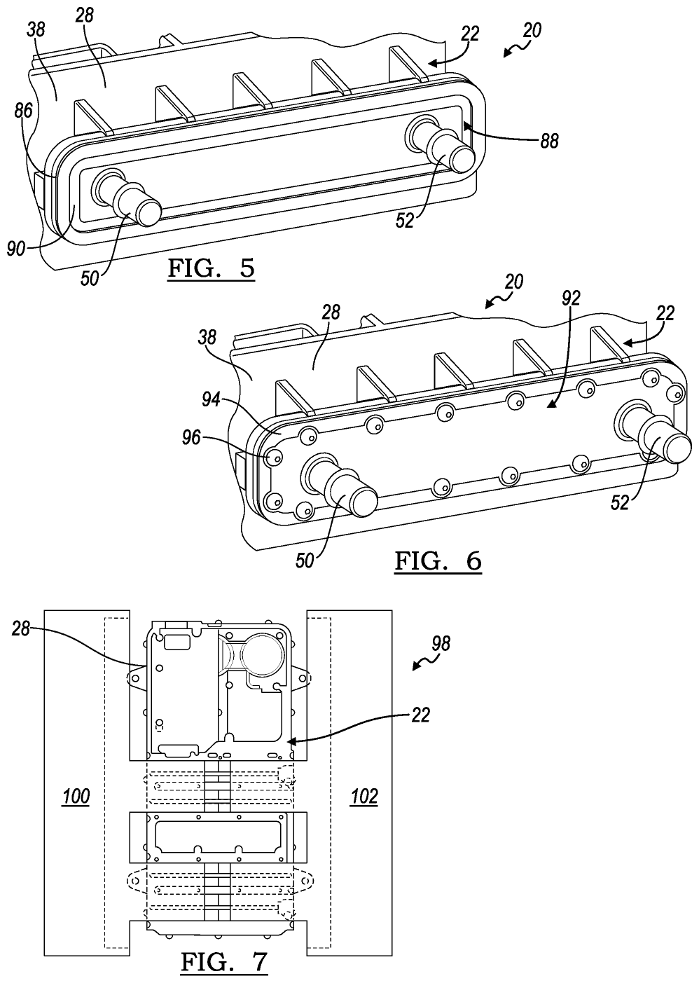

Various suitable fasteners may be employed for attaching the covers 46, 48 to the housing 22. Referring now to FIG. 5, the housing 22 may be provided with a mating surface 86 sized to receive a weld according to an embodiment. Likewise, a cover 88 may be sized to be mounted to the mating surface 86 and then welded to the mating surface 86 along weld 90. The weld 90 may be formed by friction stir-welding. Carbonell Mate et al. U.S. patent application Ser. No. 16/672,975, filed on Nov. 4, 2019 by Lear Corporation discloses suitable fluid vessel assemblies with welded connections, which is incorporated by reference herein.

FIG. 6 illustrates a cover 92 that is fastened to a mating surface 94 of the housing 22 by a plurality of threaded fasteners 96. A gasket may also be provided between the cover 92 and the mating surface 94 for sealed closure of the cavity 30 with fasteners 96 and the gasket as known in the art.

Referring to FIG. 7, the housing 22 may be cast from a thermally conductive material such as aluminum within a mold 98. The mold dies may be oriented in a height direction of the housing 22, with one stationary, and one translatable to open and close the mold 98. The mold 98 may include a pair of mold inserts 100, 102 that slide laterally after the mold 98 is closed to form the cooling channel 36. The lateral direction in FIG. 7 is in the width direction of the housing 22, which is perpendicular to the direction of the movement of the mold dies. Next, the thermally conductive material is cast into the mold and about the sliders 100, 102. After adequate cooling and hardening, the mold 98 is opened and the sliders 100, 102 are retracted for removal of the housing 22 from the mold 98. Subsequently, all mating surfaces 34, 42, 44 are machined into the housing 22. Then the covers 46, 48 are installed and the electrical components 24 are installed into the cavity 30 upon the substrate 26. The housing 22 may be formed by any suitable manufacturing method, including lost core casting, machining, or the like.

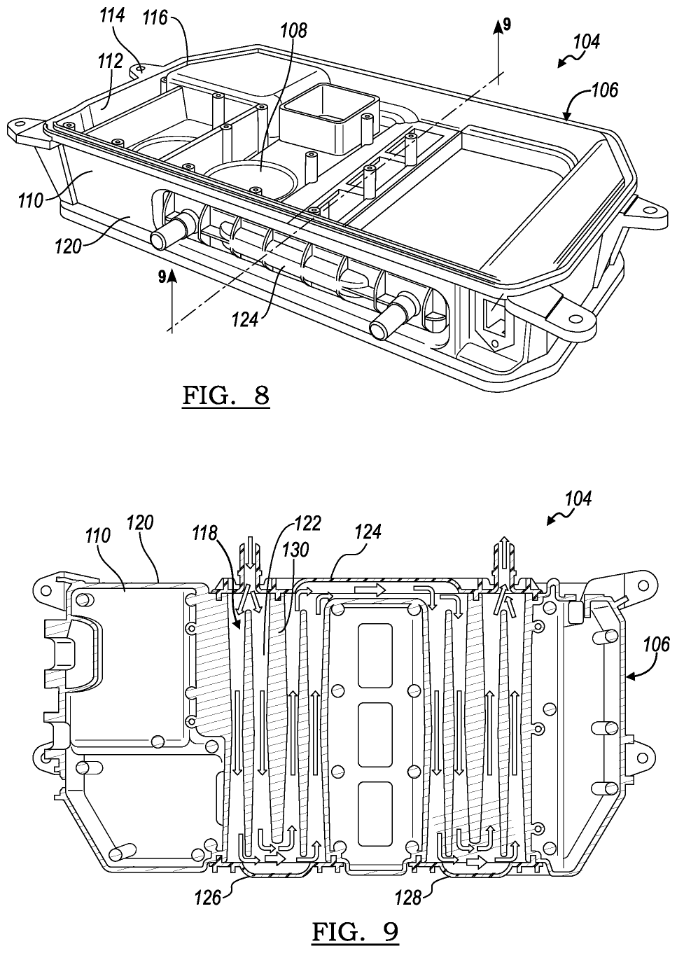

FIGS. 8 and 9 illustrate a housing assembly 104 according to another embodiment. The housing assembly 104 includes a housing 106 with a substrate 108 for receiving electrical components within sidewalls 110. The sidewalls 110 form a cavity 112 with the substrate 108 and provide an opening 114 with a mating surface 116 for a cover. Referring now to FIG. 9, a cooling channel 118 is formed between a lateral pair 120 of the sidewalls 110. The cooling channel 118 is provided by a plurality of cooling channel segments 122 that are enclosed by covers 124, 126, 128. Structural fins 130 are provided within the cooling channel segments 122. The cooling channel segments are tapered to narrow centrally to provide draft angles to remove the sliders 100, 102 after the casting operation. The draft angles are at least one degree from lateral.

While various embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A housing for electrical components comprising:
a substrate; and
sidewalls extending from the substrate to define a cavity configured to receive electrical components;
wherein a cooling channel is formed integrally along and unitary with the substrate, spaced apart from the cavity, with a mating surface for at least one fluid cover; and
at least one fluid cover mountable on the mating surface for at least one fluid cover to enclose the cooling channel and to redirect a fluid when present within the cooling channel.

2. The housing of claim 1 wherein the cooling channel is formed through a lateral pair of the sidewalls.

3. The housing of claim 1 wherein the cooling channel is enclosed within the housing except through the sidewalls.

4. The housing of claim 1 wherein the cooling channel is further defined as a plurality of cooling channels formed integrally along and unitary with the substrate, spaced apart from the cavity.

5. The housing of claim 4 wherein a plurality of mating surfaces for the at least one fluid cover is formed along the sidewalls only.

6. The housing of claim 5 wherein the plurality of mating surfaces for the at least one fluid cover is formed upon a pair of spaced apart and opposed lateral sidewalls of the housing.

7. The housing of claim 6 wherein the housing has a height in a direction parallel with the sidewalls, a width, and a length greater than the width; and
wherein the plurality of mating surfaces for the at least one fluid cover is formed along the length of the housing.

8. The housing of claim 6 further comprising a plurality of covers, each mounted to one of the plurality of mounting surfaces for the at least one fluid cover to enclose the plurality of cooling channels.

9. The housing of claim 8 wherein one of the plurality of covers limits fluid communication between a sequential pair of the plurality of cooling channels.

10. The housing of claim 8 wherein a sequential pair of the plurality of cooling channels are interconnected by a first cooling channel portion formed along one of the lateral sidewalls.

11. The housing of claim 10 wherein one of the plurality of covers provides a second cooling channel portion cooperating with the first cooling channel portion of the housing interconnecting the sequential pair of the plurality of cooling channels.

12. The housing of claim 8 wherein an inlet port and an outlet port to the plurality of cooling channels are formed in the plurality of covers.

13. The housing of claim 8 wherein each sequential pair of the plurality of cooling channels are interconnected by a first cooling channel portion formed along one of the lateral sidewalls.

14. The housing of claim 13 wherein each of the plurality of covers provides a second cooling channel portion cooperating with one of the first cooling channel portions of the housing interconnecting each sequential pair of the plurality of cooling channels.

15. The housing of claim 1 further comprising a structural fin provided within the cooling channel.

16. The housing of claim 1 wherein the cooling channel is formed with draft angles in a lateral direction to mold the housing.

17. A housing for electrical components comprising:
a substrate; and
sidewalls extending from the substrate to define a cavity to receive electrical components; and
wherein a cooling channel is formed integrally along the substrate spaced apart from the cavity and enclosed within the housing except through a lateral pair of sidewalls.

18. A method of manufacturing a housing for electrical components, the method comprising:
translating a first mold die in a first direction toward a second mold die to close a mold;
translating a pair of mold inserts centrally into a mold cavity in directions perpendicular to the first direction to provide cooling cavities in the housing;
casting thermally conductive material into the mold cavity to form the housing with a substrate generally perpendicular to the cooling cavities to receive electrical components;
translating the pair of mold inserts out of the mold cavity;
translating the first mold die away from the second mold die to open the mold; and
removing the housing from the mold cavity.

19. The method of claim 18 further comprising:
installing cooling covers on lateral sides of the housing to enclose and direct the cooling cavities; and
installing electrical components upon the substrate of the housing.

20. A housing for electrical components formed from the method of claim 18.
